(19) United States
(12) Patent Application Publication
(10) Pub. No.: US 2016/0285039 A1
(43) Pub. Date: Sep. 29, 2016

(54) ORGANIC LIGHT-EMITTING DIODE DISPLAY

(71) Applicant: SAMSUNG DISPLAY CO., LTD., Yongin-si (KR)

(72) Inventor: Mu Gyeom Kim, Hwaseong-si (KR)

(21) Appl. No.: 14/869,849

(22) Filed: Sep. 29, 2015

(30) Foreign Application Priority Data
Mar. 24, 2015 (KR) 10-2015-0041009

(51) Int. Cl. H01L 51/52; H01L 51/00; G06F 3/041; H01L 27/32

(52) U.S. Cl. CPC H01L 51/5246; H01L 27/323; H01L 51/0096; H01L 27/322; H01L 51/5284; H01L 51/5253; H01L 27/3244; G06F 3/041; H01L 2251/558; H01L 2251/301

(57) ABSTRACT

An organic light-emitting diode (OLED) display is disclosed. In one aspect, the OLED display includes a first substrate, an organic emission layer formed over the first substrate and a second substrate formed over the organic emission layer and facing the first substrate. The OLED display includes a functional layer interposed between the first and second substrates and a middle layer interposed between the organic emission layer and the functional layer. Each of the first and second substrates is formed of glass having a thickness in the range of about 50 μm to about 100 μm.

### CROSS-REFERENCE TO RELATED APPLICATION

This application claims priority to and the benefit of Korean Patent Application No. 10-2015-0041009 filed in the Korean Intellectual Property Office on Mar. 24, 2015, the entire contents of which are incorporated herein by reference.

### BACKGROUND

1. Field

The described technology generally relates to an organic light emitting diode display.

2. Description of the Related Technology

An organic light-emitting diode (OLED) includes two electrodes and an interposed organic light-emitting layer. Electrons injected from a cathode electrode and holes injected from an anode electrode are bonded to each other in the organic light-emitting layer to form excitons. Light is emitted while the excitons discharge energy.

A flexible OLED display can be easily bent and typically includes a substrate supporting the display and a window, or transparent substrate/film, covering the substrate to protect the substrate from environmental contaminants. This window must be formed of a material having an appropriate degree of flexibility. In general, a polyimide (PI) is used for the flexible substrate and a flexible protection film is used for the window.

However, during manufacturing, static electricity is easily generated in the polyimide such that there are a large number of process defects, such as impurities, and as a result, managing foreign particulates is challenging. Also, the protection film has little strength such that reliability of handling an external impact is low.

The above information disclosed in this Background section is only to enhance the understanding of the background of the disclosure, and therefore it can contain information that does not constitute the prior art that is already known in this country to a person of ordinary skill in the art.

### SUMMARY OF CERTAIN INVENTIVE ASPECTS

One inventive aspect relates to an OLED display that easily manages foreign particulates and provides greater strength with respect to bending and/or impact force.

Another aspect is an OLED display that includes a first substrate; an organic emission layer formed on the first substrate; a second substrate facing the first substrate; a functional layer formed under the second substrate; and a middle layer formed between the organic emission layer and the functional layer, wherein the first substrate and the second substrate respectively include a thin glass having a thickness of about 50 μm to about 100 μm.

The first substrate and the second substrate can be a chemical tempered glass including a potassium factor.

A coupling member positioned between an outer portion of the first substrate and an outer portion of the second substrate, and which adheres the outer portion of the first substrate to the outer portion of the second substrate, can be further included.

The coupling member can be a glass member including carbon.

The functional layer can include a touch sensor layer formed under the second substrate, and a polarization layer formed under the touch sensor layer.

The polarization layer can include a light blocking member formed under the touch sensor layer and having a plurality of light blocking openings, and a color filter formed in the light blocking openings.

A first hard coating layer formed between the touch sensor layer and the polarization layer, and a second hard coating layer formed between the polarization layer and the middle layer can be further included.

The functional layer can include a polarization layer formed under the second substrate, and a touch sensor layer formed under the polarization layer.

The polarization layer can include a light blocking member formed under the second substrate and having a plurality of light blocking openings, and a color filter formed in the light blocking openings.

A first hard coating layer formed between the touch sensor layer and the middle layer, and a second hard coating layer formed between the touch sensor layer and the polarization layer can be further included.

An encapsulation layer formed between the organic emission layer and the functional layer and covering the organic emission layer can be further included.

Another aspect is an OLED display that includes a first substrate; an organic emission layer formed on the first substrate; a second substrate facing the first substrate; a touch sensor layer formed on the second substrate; a polarization layer formed under the second substrate; and a middle layer formed between the organic emission layer and the polarization layer, wherein the first substrate and the second substrate include a thin glass having a thickness of about 50 μm to about 100 μm.

The first substrate and second substrate can be a tempered glass including a potassium factor.

A coupling member positioned between an outer portion of the first substrate and an outer portion of the second substrate, and which adheres the outer portion of the first substrate to the outer portion of the second substrate, can be further included.

The coupling member can be a glass member including a carbon.

A first hard coating layer formed on the touch sensor layer, and a second hard coating layer formed between the polarization layer and the middle layer can be further included.

An encapsulation layer formed between the organic emission layer and the polarization layer and covering the organic emission layer can be further included.

Another aspect is an organic light-emitting diode (OLED) display, comprising: a first substrate; an organic emission layer formed over the first substrate; a second substrate formed over the organic emission layer and facing the first substrate; a functional layer interposed between the first and second substrates; and a middle layer interposed between the organic emission layer and the functional layer, wherein each of the first and second substrates is formed of glass having a thickness in the range of about 50 μm to about 100 μm.

In the above OLED display, the glass includes a chemical tempered glass including potassium. The above OLED display further comprises a sealant interposed between an outer portion of the first substrate and an outer portion of the second substrate, wherein the sealant includes a sealing material connected to the outer portions of the first and second substrates. In the above OLED display, the sealant includes glass material including carbon. In the above OLED display, the functional layer includes: a touch sensor layer formed under the second substrate in the depth dimension of the OLED display, and a polarization layer formed under the touch sensor layer in the depth dimension.

In the above OLED display, the polarization layer includes: a light blocking layer formed under the touch sensor layer in the depth dimension and having a plurality of light blocking openings; and a color filter formed in the light blocking openings. The above OLED display further comprises: a first hard coating layer interposed between the touch sensor layer and the polarization layer; and a second hard coating layer interposed between the polarization layer and the planarization layer.

In the above OLED display, the functional layer includes: a polarization layer formed under the second substrate in the depth dimension of the OLED display, and a touch sensor layer formed under the polarization layer in the depth dimension. In the above OLED display, the polarization layer includes: a light blocking layer formed under the second substrate in the depth dimension and having a plurality of light blocking openings; and a color filter formed in the light blocking openings. The above OLED display further comprises: a first hard coating layer interposed between the touch sensor layer and the planarization layer; and a second hard coating layer interposed between the touch sensor layer and the polarization layer. The above OLED display further comprises an encapsulation layer interposed between the organic emission layer and the functional layer and covering the organic emission layer.

Another aspect is an organic light-emitting diode (OLED) display, comprising: a first substrate; an organic emission layer formed over the first substrate; a second substrate formed over the organic emission layer and facing the first substrate; a touch sensor layer formed over the second substrate; a polarization layer formed under the second substrate in the depth dimension of the OLED display; and a planarization layer interposed between the organic emission layer and the polarization layer, wherein each of the first and second substrate is formed of glass having a thickness in the range of about 50 μm to about 100 μm.

In the above OLED display, the glass comprises a tempered glass including potassium. The above OLED display further comprises a sealant interposed between an outer portion of the first substrate and an outer portion of the second substrate, wherein the sealant includes a sealing material connected to the outer portions of the first and second substrates. In the above OLED display, the sealant includes glass material including carbon. The above OLED display further comprises: a first hard coating layer formed over the touch sensor layer; and a second hard coating layer interposed between the polarization layer and the planarization layer. The above OLED display further comprises an encapsulation layer interposed between the organic emission layer and the polarization layer and covering the organic emission layer.

Another aspect is an organic light-emitting diode (OLED) display, comprising: a first substrate; a second substrate separated from the first substrate; a touch sensor layer formed closer to the second substrate than the first substrate; an organic emission layer formed closer to the first substrate than the second substrate; and a sealant formed at outer portions of the first and second substrates, wherein the sealant includes a sealing material contacting the outer portions of the first and second substrates, wherein each of the first and second substrates is formed of glass having a thickness greater than the thickness of the touch sensor layer.

In the above OLED display, the thickness of each of the first and second substrates is in the range of about 50 μm to about 100 μm. The above OLED display further comprises a polarization layer formed closer to the touch sensor layer than the organic emission layer, wherein the polarization layer includes: a light blocking layer formed in a first region and configured to block light emitted from the organic emission layer; and a color filter formed in a second region and configured to apply color to and transmit the light emitted from the organic light emission layer.

According to at least one of the disclosed embodiments of the present disclosure, by forming the first substrate used as the supporting substrate of the organic emission layer of the thin glass substrate, flexibility can be obtained and concurrently the generation of static electricity can be reduced, thereby easily managing foreign matter.

Also, by forming the second substrate used as the window of the thin glass substrate, the strength of the window is improved such that the reliability against external impacts can be increased.

Also, by chemically strengthening the first substrate and the second substrate that are made of the thin glass or by forming the first hard coating layer and the second hard coating layer under or on the second substrate, the flexibility and the hardness of the OLED display can be simultaneously satisfied.

### BRIEF DESCRIPTION OF THE DRAWINGS

FIG. 1 is a schematic cross-sectional view of an OLED display according to an exemplary embodiment of the present disclosure.

FIG. 2 is an equivalent circuit diagram of an organic emission layer of an OLED display according to an exemplary embodiment of the present disclosure.

FIG. 3 is a detailed cross-sectional view of an OLED display according to an exemplary embodiment of the present disclosure.

FIG. 4 is a detailed cross-sectional view of an OLED display according to another exemplary embodiment of the present disclosure.

FIG. 5 is a detailed cross-sectional view of an OLED display according to another exemplary embodiment of the present disclosure.

FIG. 6 is a detailed cross-sectional view of an OLED display according to another exemplary embodiment of the present disclosure.

### DETAILED DESCRIPTION OF CERTAIN INVENTIVE EMBODIMENTS

The present disclosure will be described more fully hereinafter with reference to the accompanying drawings, in which exemplary embodiments of the disclosure are shown. As those skilled in the art would realize, the described embodiments can be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited thereto. In the drawings, the thickness of layers, films, panels, regions, etc., are exaggerated for clarity. In the drawings, for better understanding and ease of description, the thicknesses of some layers and areas are exaggerated.

In the specification, unless explicitly described to the contrary, the word “comprise” and variations such as “comprises” or “comprising” will be understood to imply the inclusion of stated elements but not the exclusion of any other elements. In addition, it will be understood that when an element such as a layer, film, region, or substrate is referred to as being “on” another element, it can be directly on the other element or intervening elements can also be present. In contrast, when an element is referred to as being “directly on” another element, there are no intervening elements present. Further, in the specification, the word “on” means positioning on or below the object portion, and does not essentially mean positioning on the upper side of the object portion based on a direction of gravity.

Further, in the specification, the word “on a flat surface” means when an object portion is viewed from the above, and the word “on a cross section” means when a cross section taken by vertically cutting an object portion is viewed from the side.

Further, the present disclosure is not limited to the number of thin film transistors TFT and capacitors illustrated in the accompanying drawings, and the OLED display can include a plurality of thin film transistors and one or more capacitors in one pixel, and a separate wire can be further formed or a known wire can be omitted to provide various structures. Here, the pixel means a minimum unit displaying an image, and the OLED display displays an image through a plurality of pixels. In this disclosure, the term “substantially” includes the meanings of completely, almost completely or to any significant degree under some applications and in accordance with those skilled in the art. The term “connected” can include an electrical connection.

Now, an OLED display according to an exemplary embodiment of the present disclosure will be described in detail with reference to the accompanying drawings.

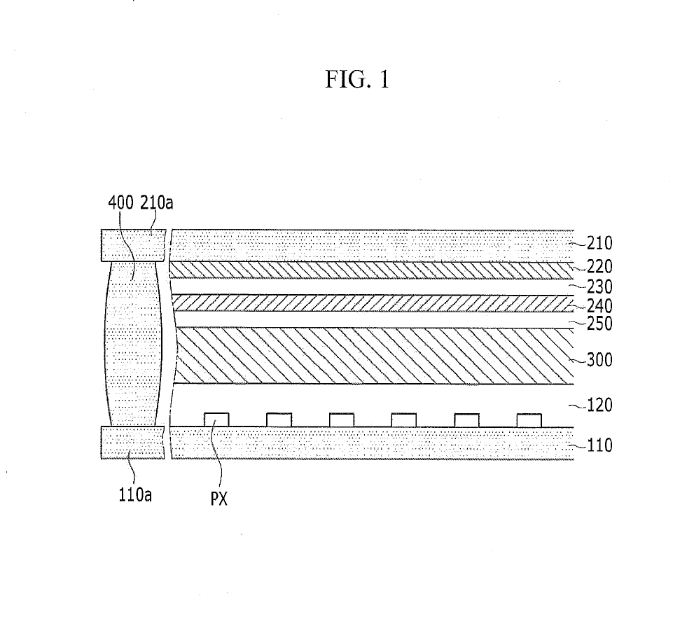

FIG. 1 is a schematic cross-sectional view of an OLED display according to an exemplary embodiment of the present disclosure.

As shown in FIG. 1, an OLED display according to an exemplary embodiment of the present disclosure includes a first substrate 110 and an organic emission layer 120 formed on the first substrate 110. Also, a second substrate 210 facing the first substrate 110 and covering the first substrate 110 and functional layers 220 and 240 formed under the second substrate 210 are included. The functional layers 220 and 240 include a touch sensor layer 220 formed under the second substrate 210 and functioning as a means for information input and a polarization layer 240 that is formed under the touch sensor layer 220 and that removes reflection of external light. A first hard coating layer 230 protecting the touch sensor layer 220 is formed under the touch sensor layer 220, a second hard coating layer 250 protecting the polarization layer 240 is formed under the polarization layer 240, and a middle layer (or planarization layer) 300 is formed between the organic emission layer 120 and the second hard coating layer 250.

The first substrate 110 can include a thin glass sheet having a thickness of about 50 μm to about 100 μm. In a case where the first substrate 110 is formed of a polymer such as PI to improve flexibility, when hardening the polymer, a lot of impurities are generated such that there are a large number of process defects. Further, the surface charges are increased such that static electricity is generated, thereby requiring the management of foreign matter. However, when the first substrate 110 is formed of the thin glass, the impurities and the static electricity are not generated such that the additional management of foreign matter is not required. Also, when the first substrate 110 is formed of thin glass, the first substrate 110 has greater strength than polyimide such that the impact resistance is also high.

This first substrate 110 can be a chemical tempered glass. The chemical tempered glass is a glass of which the surface hardness is enhanced by replacing a sodium factor as one of basic components of a glass composition with a potassium factor to generate a compress stress in the surface of the glass. The chemical tempered glass is thinner than a general tempered glass and is more than about 1.7 times stronger, and there is no phenomenon such as shrinkage or a warping caused by the process of the general tempered glass.

The organic emission layer 120 includes a plurality of pixels PX emitted through a top surface.

The second substrate 210 can include the thin glass having the thickness of about 50 μm to about 100 μm. In a case where the second substrate 210 is formed of a polymer such as PI to improve flexibility, when hardening the polymer, a lot of impurities are generated such that there is a large number of process defects. Further, the surface charges are increased such that static electricity is generated, thereby requiring the management of foreign matter. However, when the first substrate 210 is formed of the thin glass, the impurities and the static electricity are not generated such that the additional management of foreign matter is not required. Also, when the second substrate 210 is formed of the thin glass, the first substrate 110 has greater strength than polyimide such that the impact reliability is also high.

The second substrate 210 can be the chemical tempered glass including the potassium factor. The chemical tempered glass is thinner than a general tempered glass and is more than about 1.7 times stronger, and there is no phenomenon such as shrinkage or a warping caused by the process of the general tempered glass

As described above, by manufacturing the first substrate used as a supporting substrate of the organic emission layer 120 of the thin glass substrate, flexibility can be obtained and simultaneously (or concurrently) static electricity is not generated, thereby easily managing foreign matter.

Also, by manufacturing the second substrate used as the window of the thin glass substrate, the strength of the window is improved such that the reliability against external impacts can be increased.

A coupling member or sealant 400 is positioned between the outer portion 110a of the first substrate 110 and the outer portion 210a of the second substrate 210. The coupling member 400 adheres the outer portion 110a of the first substrate 110 to the outer portion 210a of the second substrate 210. The coupling member 400 can be a glass member including carbon. As described above, since the coupling member 400 is formed of the same material as the first substrate and the second substrate, when adhering the outer portion 110a of the first substrate 110 to the outer portion 210a of the second substrate 210 through the laser hardening, the outer portion 110a of the first substrate 110 and the outer portion 210a of the second substrate 210 are continuously formed without the boundary portion such that the inner portion can be further completely sealed. Accordingly, since an additional encapsulation layer covering the organic emission layer 120 can be omitted, a formation process of the encapsulation layer that requires a lot of processing time can be omitted such that manufacturing time can be shorted.

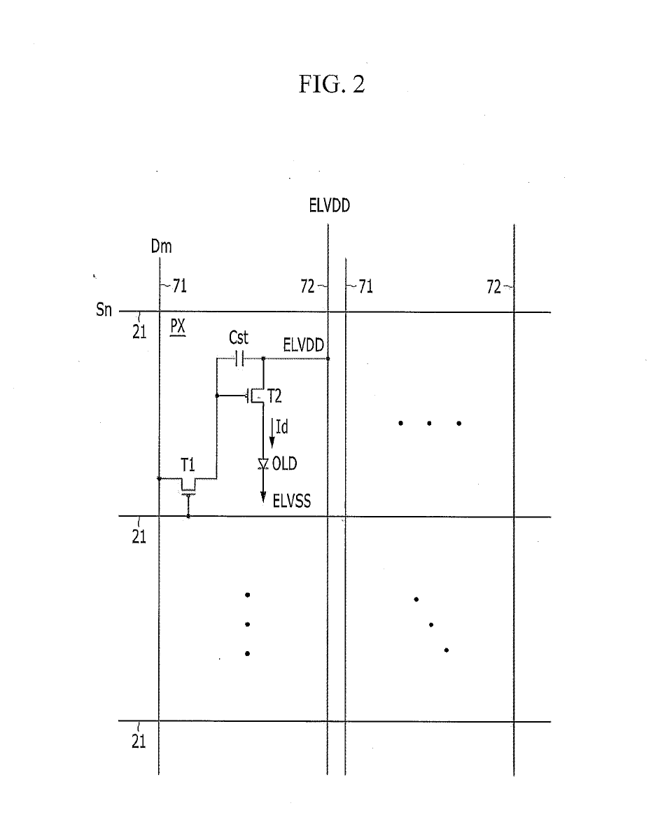

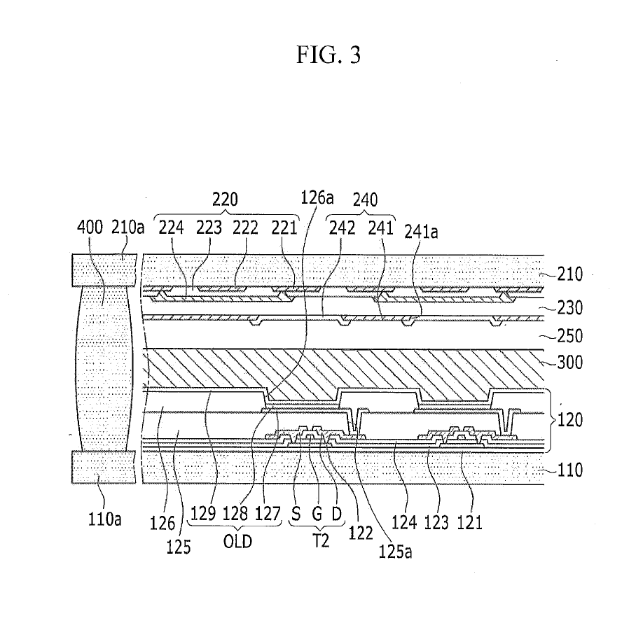

Next, a detailed structure of the OLED display according to an exemplary embodiment of the present disclosure will be described with reference to FIG. 2 and FIG. 3.

FIG. 2 is an equivalent circuit diagram of an organic emission layer of an OLED display according to an exemplary embodiment of the present disclosure. FIG. 3 is a detailed cross-sectional view of an OLED display according to an exemplary embodiment of the present disclosure.

As shown in FIG. 2, an organic emission layer 120 of the OLED display according to an exemplary embodiment of the present disclosure includes a plurality of signal lines 21, 71, and 72, and a plurality of pixels PX connected to the plurality of signal lines and arranged in an approximate matrix type. The signal lines 21, 71, and 72 include a plurality of scan lines 21 transmitting a scan signal Sn, a plurality of data lines 71 crossing the scan lines 21 and transmitting a data signal Dm, and a plurality of driving voltage lines 72 transmitting a driving voltage ELVDD and being substantially parallel to the data lines 71. The gate lines 21 extend substantially parallel with one another in a row direction (or a first direction), and the data lines 71 and the driving voltage lines 72 extend substantially parallel with one another in a column direction (or a second direction crossing the first direction).

Each pixel PX includes a plurality of transistors T1 and T2 respectively connected to the signal lines 21, 71, and 72, a storage capacitor Cst, and an OLED OLD.

The transistors T1 and T2 include a switching transistor T1 connected to the data line 71, and a driving transistor T2 connected to the OLED OLD.

The switching transistor T1 includes a control terminal, an input terminal, and an output terminal, and the control terminal thereof is connected to the scan line 21, the input terminal thereof is connected to the data line 71, and the output terminal thereof is connected to the driving transistor T2. The switching transistor T1 transmits the data signal Dm applied to the data line 71 to the driving transistor T2 in response to the scan signal Sn applied to the scan line 21.

The driving transistor T2 also includes a control terminal, an input terminal, and an output terminal, and the control terminal thereof is connected to the switching transistor T1, the input terminal thereof is connected to the driving voltage line 72, and the output terminal thereof is connected to the OLED OLD. The driving transistor T2 allows a driving current Id, which has a level varying according to a voltage applied between the control terminal and the output terminal, to flow.

The storage capacitor Cst is connected between the control terminal and the input terminal of the driving transistor T2. The storage capacitor Cst charges the data signal applied to the control terminal of the driving transistor T2 and maintains the data signal even after the switching transistor T1 is turned off.

The OLED OLD includes an anode that is connected to the output terminal of the driving transistor T2, and a cathode that is connected to the common voltage ELVSS. The OLED OLD emits light with an intensity varying according to the driving current Id of the driving transistor T2, thereby displaying an image.

The switching transistor T1 and the driving transistor T2 can be an n-channel field effect transistor FET or a p-channel field effect transistor. In addition, a connection relationship among the transistors T1 and T2, the storage capacitor Cst, and the OLED OLD can be changed.

Next, a structure of the OLED display according to the exemplary embodiment of the present disclosure will be described in detail with reference to FIG. 3. In this case, the structure of the pixel area P will be described based on the driving transistor, and the switching transistor substantially has the same stack structure as that of the driving transistors, and thus a detailed description thereof will be omitted.

As shown in FIG. 3, a buffer layer 121 is formed on the first substrate 110. The buffer layer 120 can serve to improve a characteristic of polycrystalline silicon and reduce stress applied to the semiconductor 122 formed on the buffer 121 by blocking impurities from the substrate 110 and flattening the first substrate 110 during a crystallization process for forming polycrystalline silicon. The buffer layer 121 can be formed of silicon nitride (SiNx) or silicon oxide (SiO2).

The semiconductor 122 is formed on the buffer layer 121. The semiconductor 122 can be formed of polycrystalline silicon or an oxide semiconductor. A gate insulating layer 123 covering the semiconductor 122 is formed thereon. The gate insulating layer 123 can be formed of silicon nitride (SiNx) or silicon oxide (SiO2).

A gate electrode G1 is formed on the gate insulating layer 123. The gate electrode G is a part of the scan line 21 and overlaps the semiconductor 122.

An interlayer insulating layer 124 covering the gate electrode G is formed thereon. The interlayer insulating layer 124 can be formed of silicon nitride (SiNx) or silicon oxide (SiO2) like the gate insulating layer 123.

A source electrode S and a drain electrode D are formed on the interlayer insulating layer 124. The source electrode S and the drain electrode D are respectively connected to the source region and the drain region of the semiconductor 122. The gate electrode G, the source electrode S, and the drain electrode D form a driving transistor T2.

A passivation layer 125 covering the source electrode S and the drain electrode D is formed thereon. A pixel electrode 127 formed of a reflective conductive material such as lithium (Li), calcium (Ca), lithium fluoride/calcium (LiF/Ca), lithium fluoride /aluminum (LiF/Al), aluminum (Al), silver (Ag), magnesium (Mg), or gold (Au) is formed on the passivation layer 125. The pixel electrode 127 is electrically connected to the drain electrode D of the driving transistor T2 through the contact hole 125a formed in the passivation layer 125, thereby being an anode of the OLED OLD.

A partition 126 is formed on the passivation layer 125 and the edge of the pixel electrode 127. The partition 126 has a pixel opening 126a exposing the pixel electrode 127. The partition 126 can be formed to include a resin, such as polyacrylates or polyimides, and a silica-based inorganic material, or the like.

An organic light emission member 128 is formed in the pixel opening 126a of the pixel partition 126. The organic light emission layer 128 can have multiple layers including one or more of a light emission layer, a hole injection layer (HIL), a hole transporting layer (HTL), an electron transporting layer (ETL), and an electron injection layer (EIL). When the organic light emission layer 128 includes all of the light emission layer, the hole injection layer (HIL), the hole transporting layer (HTL), the electron transporting layer (ETL), and the electron injection layer (EIL), the hole injection layer is positioned on the pixel electrode 127, which is the anode, and the hole transporting layer, the light emission layer, the electron transporting layer, and the electron injection layer are sequentially stacked on the hole injection layer.

A common electrode 129 formed of a transparent conductive material such as ITO(Indium Tin Oxide), ITO(Indium Zinc Oxide), ZnO(zinc oxide), or In₂O₃(Indium Oxide) is formed on the partition 126 and the organic light emitting member 128. The common electrode 129 becomes a cathode of the OLED OLD. The pixel electrode 127, the organic light emitting member 128, and the common electrode 129 together form an OLED OLD.

Meanwhile, the touch sensor layer 220 adhered under the second substrate 210 as an input device of the OLED display inputs the information through a screen being directly contacted by a finger or a pen. The touch sensor layer 220 is formed under the second substrate 210 and includes a Tx touch electrode (a transmitter touch electrode) 221 transmitting a first touch signal sensing a first axis coordinate value and a Rx touch electrode (a receiver touch electrode) 222 transmitting a second touch signal sensing a second axis coordinate value. The Tx touch electrode 221 and the Rx touch electrode 222 are separated from each other and can be formed of low resistance metal such as indium tin oxide (ITO), carbon nanotube (CNT), graphene, or Al, Cu, Cr, Ni. An insulating layer 223 covering the Tx touch electrode 221 and the Rx touch electrode 222 is formed thereon. The insulating layer 223 can be formed of silicon oxide or silicon nitride. A connecting member 224 connecting a plurality of Tx touch electrodes 221 to each other is formed on the insulating layer 223. If the user directly contacts the screen with a finger or pen, the touch sensor layer 220 senses the position where a capacitance change depending on the contact is generated through the Tx touch electrode 221 and the Rx touch electrode 222 to determine the position information.

The first hard coating layer 230 formed under the touch sensor layer 220 covers the touch sensor layer 220 to protect the touch sensor layer 220. The first hard coating layer 230 includes a siloxane-based compound, the siloxane-based compound is formed of any one among poly ether modified poly dimethyl siloxane or poly dimethyl siloxane of poly ether modified hydroxyl functional group or a combination of two or more thereof, that is, examples of the siloxane-based compound are BYK-306 (BYK chemi agent), BYK-307, BYK-308, BYK-310, BYK-330, BYK-333, BYK-341, BYK-344.

The polarization layer 240 is formed on the second substrate 210 and includes a light blocking member (or light blocking layer) 241 blocking a light and a color filter 242 formed in a plurality of light blocking openings 241a of the light blocking member 241. The light blocking member 241 can be formed of a metal such as chromium (Cr) or an organic material, and the color filter 242 can partially overlap the light blocking member 241.

The second hard coating layer 250 formed under the polarization layer 240 covers the polarization layer 240 to protect the polarization layer 240. The second hard coating layer 250 includes a siloxane-based compound, the siloxane-based compound is formed of any one among poly ether modified poly dimethyl siloxane or poly dimethyl siloxane of poly ether modified hydroxyl functional group or a combination of two or more thereof, that is, examples of the siloxane-based compound are BYK-306 (BYK chemi agent), BYK-307, BYK-308, BYK-310, BYK-330, BYK-333, BYK-341, BYK-344.

As described above, by forming the first hard coating layer 230 covering the touch sensor layer 220 and the second hard coating layer 250 covering the polarization layer 240, the hardness of the second substrate 210 as the glass substrate having the thin thickness of 50 μm to 100 μm can be improved.

The middle layer 300 can include a transparent silicon hygroscopic filler. The middle layer 300 is filled between the organic emission layer 120 and the second hard coating layer 250 to be flattened and protects the organic emission layer 120 from external moisture.

Meanwhile, in the exemplary embodiment shown in FIG. 1, FIG. 2, and FIG. 3, the encapsulation layer is not formed, but the encapsulation layer covering the organic emission layer can be formed as another exemplary embodiment.

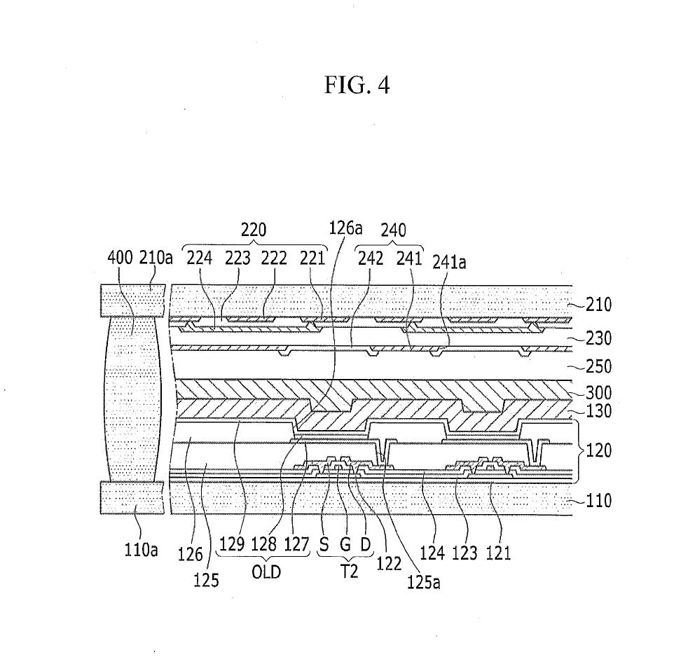

Next, an OLED display according to another exemplary embodiment of the present disclosure will be described with reference to FIG. 4.

FIG. 4 is a cross-sectional view of an OLED display according to another exemplary embodiment of the present disclosure.

The other exemplary embodiment shown in FIG. 4 is substantially the same as the exemplary embodiment shown in FIG. 1, FIG. 2, and FIG. 3, except for the encapsulation layer, such that the duplicate description thereof is omitted.

As shown in FIG. 4, the OLED display according to another exemplary embodiment of the present disclosure includes a first substrate 110, an organic emission layer 120 formed on the first substrate 110 and emitting the light, and an encapsulation layer 130 covering the organic emission layer 120. Also, a second substrate 210 facing the first substrate 110 and covering the first substrate 110 and functional layers 220 and 240 formed under the second substrate 210 are included. The functional layers 220 and 240 include a touch sensor layer 220 formed under the second substrate 210 and functioning as a means for an information input and a polarization layer 240 formed under the touch sensor layer 220 and removing a reflection of external light. A first hard coating layer 230 protecting the touch sensor layer 220 is formed under the touch sensor layer 220, a second hard coating layer 250 protecting the polarization layer 240 is formed under the polarization layer 240, and a middle layer 300 is formed between the organic emission layer 120 and the second hard coating layer 250.

The encapsulation layer 130 can be formed of the thin film encapsulation layer in which the organic layer and the inorganic layer are alternately deposited. As described above, by forming the encapsulation layer 130, the organic emission layer 120 can be further completely protected from external moisture.

The middle layer 300 can include a pressure sensitive adhesive (PSA), which is an adhesive in which the adhesive material acts when pressure for adhering the adhesive to an adhesive surface is applied. The middle layer 300 including the pressure sensitive adhesive (PSA) further strongly adheres the encapsulation layer 130 and the second hard coating layer 250 compared to the case using the transparent silicon hygroscopic filler.

On the other hand, in the exemplary embodiment shown in FIG. 4, the touch sensor layer and the polarizer are sequentially formed under the second substrate. However the polarizer and the touch sensor layer can be sequentially formed under the second substrate as another exemplary embodiment.

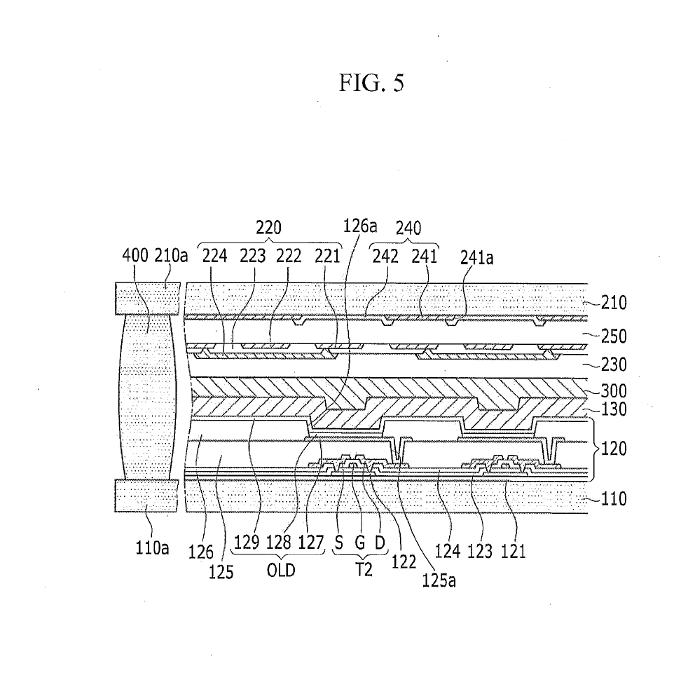

Next, an OLED display according to another exemplary embodiment of the present disclosure will be described with reference to FIG. 5.

FIG. 5 is a cross-sectional view of an OLED display according to another exemplary embodiment of the present disclosure.

The other exemplary embodiment shown in FIG. 5 is substantially the same as the exemplary embodiment shown in FIG. 4, except for the deposit order of the polarizer and the touch sensor layer such that the duplicate description thereof is omitted.

As shown in FIG. 5, the OLED display according to another exemplary embodiment of the present disclosure includes a first substrate 110, an organic emission layer 120 formed on the first substrate 110 and emitting the light, and an encapsulation layer 130 covering the organic emission layer 120. Also, a second substrate 210 facing the first substrate 110 and covering the first substrate 110 and functional layers 220 and 240 formed under the second substrate 210 are included. The functional layers 220 and 240 include the polarization layer 240 formed under the second substrate 210 and removing the reflection of external light and the touch sensor layer 220 formed under the polarization layer 240 and functioning as the means for the information input. The first hard coating layer 230 protecting the touch sensor layer 220 is formed under the touch sensor layer 220, the second hard coating layer 250 protecting the polarization layer 240 is formed under the polarization layer 240, and the middle layer 300 is formed between the encapsulation layer 130 and the first hard coating layer 230.

As described above, by positioning the polarization layer 240 directly under the second substrate 210, the reflection of the external reflection can be further suppressed. Also, by positioning the polarization layer 240 on the touch sensor layer 220, the touch sensor layer 220 can be prevented from being recognized compared to the case in which the polarization layer 240 is positioned under the touch sensor layer 220.

Meanwhile, in the exemplary embodiment shown in FIG. 5, the polarizer and the touch sensor layer are all formed under the second substrate. However, the polarizer and the touch sensor layer can be divided under and on the second substrate as another exemplary embodiment.

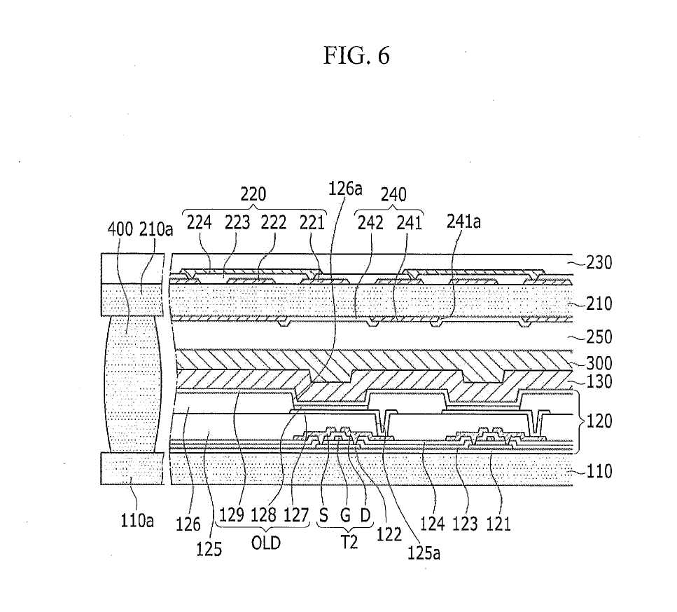

Next, an OLED display according to another exemplary embodiment of the present disclosure will be described with reference to FIG. 6.

FIG. 6 is a cross-sectional view of an OLED display according to another exemplary embodiment of the present disclosure.

The other exemplary embodiment shown in FIG. 6 is substantially the same as the exemplary embodiment shown in FIG. 5, except for the polarizer and the touch sensor layer that are divided under and on the second substrate, such that the duplicate description thereof is omitted.

As shown in FIG. 6, the OLED display according to another exemplary embodiment of the present disclosure includes a first substrate 110, an organic emission layer 120 formed on the first substrate 110 and emitting the light, and an encapsulation layer 130 covering the organic emission layer 120. Also, the second substrate 210 facing the first substrate 110 and covering the first substrate 110, the polarization layer 240 formed under the second substrate 210, the second hard coating layer 250 formed under the polarization layer 240, the touch sensor layer 220 formed on the second substrate 210, the first hard coating layer 230 formed on the touch sensor layer 220, and the middle layer 300 interposed between the encapsulation layer 130 and the second hard coating layer 250 are included.

As described above, by forming the touch sensor layer 220 on the second substrate 210, the distance between the touch sensor layer 220 and the organic emission layer 120 is farther such that a parasitic capacitor between the touch sensor layer 220 and the common electrode 129 in the organic emission layer 120 can be minimized.

While the inventive technology has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. An organic light-emitting diode (OLED) display, comprising:
a first substrate;
an organic emission layer formed over the first substrate;
a second substrate formed over the organic emission layer and facing the first substrate;
a functional layer interposed between the first and second substrates; and
a middle layer interposed between the organic emission layer and the functional layer,
wherein each of the first and second substrates is formed of glass having a thickness in the range of about 50 μm to about 100 μm.

2. The OLED display of claim 1, wherein the glass includes a chemical tempered glass including potassium.

3. The OLED display of claim 1, further comprising a sealant interposed between an outer portion of the first substrate and an outer portion of the second substrate, wherein the sealant includes a sealing material connected to the outer portions of the first and second substrates.

4. The OLED display of claim 3, wherein the sealant includes glass material including carbon.

5. The OLED display of claim 1, wherein the functional layer includes:
a touch sensor layer formed under the second substrate in the depth dimension of the OLED display, and
a polarization layer formed under the touch sensor layer in the depth dimension.

6. The OLED display of claim 5, wherein the polarization layer includes:
a light blocking layer formed under the touch sensor layer in the depth dimension and having a plurality of light blocking openings; and
a color filter formed in the light blocking openings.

7. The OLED display of claim 5, further comprising:
a first hard coating layer interposed between the touch sensor layer and the polarization layer; and
a second hard coating layer interposed between the polarization layer and the planarization layer.

8. The OLED display of claim 1, wherein the functional layer includes:
a polarization layer formed under the second substrate in the depth dimension of the OLED display, and
a touch sensor layer formed under the polarization layer in the depth dimension.

9. The OLED display of claim 8, wherein the polarization layer includes:
a light blocking layer formed under the second substrate in the depth dimension and having a plurality of light blocking openings; and
a color filter formed in the light blocking openings.

10. The OLED display of claim 8, further comprising:
a first hard coating layer interposed between the touch sensor layer and the planarization layer; and
a second hard coating layer interposed between the touch sensor layer and the polarization layer.

11. The OLED display of claim 1, further comprising an encapsulation layer interposed between the organic emission layer and the functional layer and covering the organic emission layer.

12. An organic light-emitting diode (OLED) display, comprising:
a first substrate;
an organic emission layer formed over the first substrate;
a second substrate formed over the organic emission layer and facing the first substrate;
a touch sensor layer formed over the second substrate;
a polarization layer formed under the second substrate in the depth dimension of the OLED display; and
a planarization layer interposed between the organic emission layer and the polarization layer,
wherein each of the first and second substrate is formed of glass having a thickness in the range of about 50 μm to about 100 μm.

13. The OLED display of claim 12, wherein the glass comprises a tempered glass including potassium.

14. The OLED display of claim 12, further comprising a sealant interposed between an outer portion of the first substrate and an outer portion of the second substrate, wherein the sealant includes a sealing material connected to the outer portions of the first and second substrates.

15. The OLED display of claim 14, wherein the sealant includes glass material including carbon.

16. The OLED display of claim 12, further comprising:
a first hard coating layer formed over the touch sensor layer; and
a second hard coating layer interposed between the polarization layer and the planarization layer.

17. The OLED display of claim 12, further comprising an encapsulation layer interposed between the organic emission layer and the polarization layer and covering the organic emission layer.

18. An organic light-emitting diode (OLED) display, comprising:
a first substrate;
a second substrate separated from the first substrate;
a touch sensor layer formed closer to the second substrate than the first substrate;
an organic emission layer formed closer to the first substrate than the second substrate; and
a sealant formed at outer portions of the first and second substrates, wherein the sealant includes a sealing material contacting the outer portions of the first and second substrates,
wherein each of the first and second substrates is formed of glass having a thickness greater than the thickness of the touch sensor layer.

19. The OLED display of claim 18, wherein the thickness of each of the first and second substrates is in the range of about 50 μm to about 100 μm.

20. The OLED display of claim 19, further comprising a polarization layer formed closer to the touch sensor layer than the organic emission layer, wherein the polarization layer includes:
a light blocking layer formed in a first region and configured to block light emitted from the organic emission layer; and
a color filter formed in a second region and configured to apply color to and transmit the light emitted from the organic light emission layer.
